(19) United States
(12) Patent Application Publication
(10) Pub. No.: US 2008/0272823 A1
(43) Pub. Date: Nov. 6, 2008

(54) JFET Passgate Circuit and Method of Operation

(75) Inventors: Abhijit Ray, Sunnyvale, CA (US); Damodar R. Thummalapally, Milpitas, CA (US)

Correspondence Address: BAKER BOTTS L.L.P., 2001 ROSS AVENUE, SUITE 600, DALLAS, TX, 75201-2980, US

(73) Assignee: DSM Solutions, Inc.

(21) Appl. No.: 11/743,932

(22) Filed: May 3, 2007

(51) Int. Cl. H03K 17/06

(52) U.S. Cl. 327/383

(57) ABSTRACT

A passgate circuit comprises a first depletion mode n-channel JFET, a depletion mode p-channel JFET, and a second depletion mode n-channel JFET. The first depletion mode n-channel JFET has a first terminal coupled to an input port, a second terminal that receives a first control signal, and a third terminal. The depletion mode p-channel JFET has a first terminal coupled to the third terminal of the first depletion mode n-channel JFET, a second terminal that receives a second control signal, and a third terminal. The second depletion mode n-channel JFET has a first terminal coupled to the third terminal of the depletion mode p-channel JFET, a second terminal that receives the first control signal, and a third terminal coupled to an output port.

### TECHNICAL FIELD OF THE INVENTION

The present invention relates in general to passgate circuits, and more particularly to a JFET passgate circuit.

### BACKGROUND OF THE INVENTION

A conventional passgate circuit uses complementary-metal-oxide-semiconductor (CMOS) transistors. In particular, it is made by the parallel combination of an NMOS and a pMOS transistor with the input at the gate of one transistor (nNMOS) being complementary to the input at the gate of the other transistor (pMOS). Because CMOS transistors are enhancement mode devices, the resulting passgate circuit has a high resistivity in an “on” condition. As a result, the conventional passgate circuit may experience a voltage drop from input port to output port, and may operate with an undesirable time delay.

### SUMMARY OF THE INVENTION

In accordance with the present invention, the disadvantages and problems associated with prior passgate circuits have been substantially reduced or eliminated.

In accordance with one embodiment of the present invention, a pass-gate circuit comprises a first depletion mode n-channel JFET, a depletion mode p-channel JFET, and a second depletion mode n-channel JFET. The first depletion mode n-channel JFET has a first terminal coupled to an input port, a second terminal that receives a first control signal, and a third terminal. The depletion mode p-channel JFET has a first terminal coupled to the third terminal of the first depletion mode n-channel JFET, a second terminal that receives a second control signal, and a third terminal. The second depletion mode n-channel JFET has a first terminal coupled to the third terminal of the depletion mode p-channel JFET, a second terminal that receives the first control signal, and a third terminal coupled to an output port.

In accordance with another embodiment of the present invention, a method for operating a passgate circuit comprises receiving a first control signal at a first depletion mode n-channel JFET coupled to an input port. The method further comprises receiving the first control signal at a second depletion mode n-channel JFET coupled to an output port. The method further comprises receiving a second control signal at a depletion mode p-channel JFET coupled to the first and second depletion mode n-channel JFETs. The JFETs operate such that at least one of the JFETs is turned off if the first control signal is at a low voltage and the second control signal is at a high voltage. The JFETs operate such that each of the JFETs is turned on if the first control signal is at a high voltage and the second control signal is at a low voltage.

The following technical advantages may be achieved by some, none, or all of the embodiments of the present invention.

By using depletion mode transistors such as JFETs rather than enhancement mode devices like CMOS transistors, the current between the input port and output port of the passgate circuit is stronger. As a result, the resistivity of the pass-gate circuit is lower (and the conductivity is higher) than a comparable passgate circuit that uses enhancement mode transistors. In addition, the passgate circuit does not need to use any level translators in order to create appropriate voltages to turn off one or more transistors. Furthermore, the passgate circuit does not experience a voltage drop from the input port to output port due to threshold voltages of the JFETs. Instead, a full rail-to-rail voltage swing is achievable from the input port to the output port. In this regard, whatever voltage that is applied at the input port is communicated to the output port.

These and other advantages, features, and objects of the present invention will be more readily understood in view of the following detailed description, drawings, and claims.

### BRIEF DESCRIPTION OF THE DRAWINGS

For a more complete understanding of the present invention and its advantages, reference is now made to the following descriptions, taken in conjunction with the accompanying drawings, in which:

FIG. 1 illustrates one embodiment of a junction field effect transistor (JFET) passgate circuit according the present invention; and

FIG. 2 is one embodiment of a table that illustrates the operational characteristics of the passgate circuit of FIG. 1.

### DETAILED DESCRIPTION OF THE INVENTION

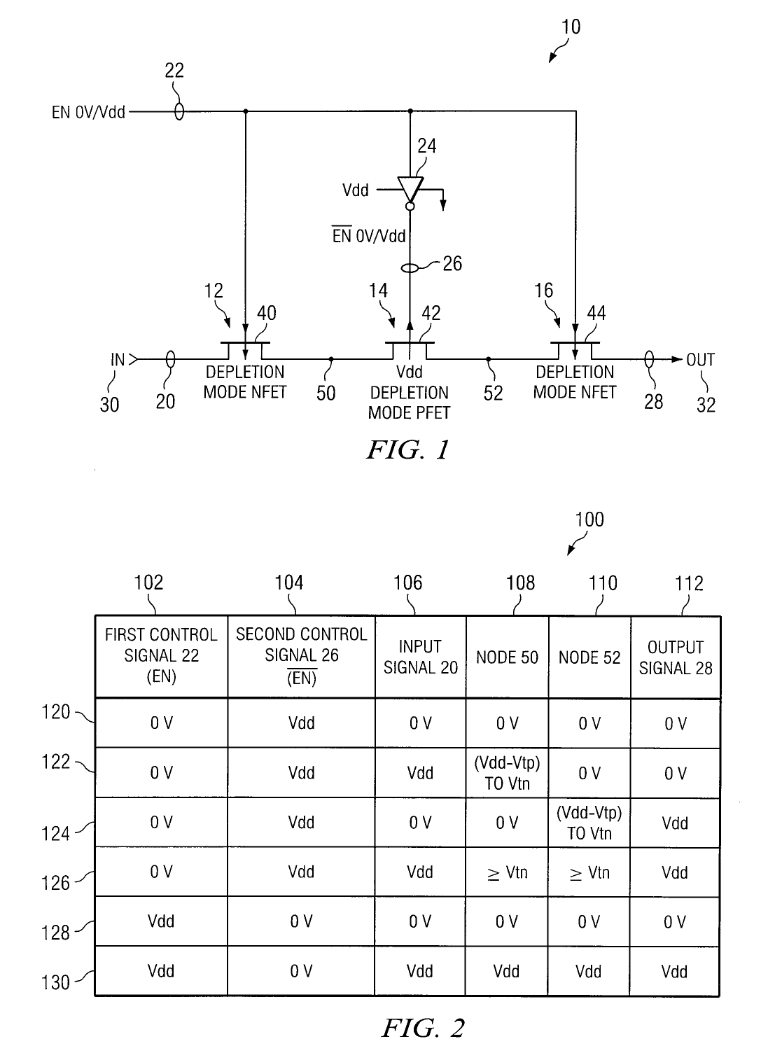

FIG. 1 illustrates one embodiment of a passgate circuit 10 comprising a first depletion mode n-channel JFET 12, a depletion mode p-channel JFET 14, and a second depletion mode n-channel JFET 16. First depletion mode n-channel JFET 12 receives an input voltage signal 20 and a first control signal 22. An inverter 24 receives first control signal 22 and generates a second control signal 26 in response thereto. Depletion mode p-channel JFET 14 is coupled to JFET 12 at node 50 and receives second control signal 26. Second depletion mode n-channel JFET 16 is coupled to depletion mode p-channel JFET 14 at node 52 and receives first control signal 22. JFET 16 outputs an output voltage signal 28. In general, JFETs 12-16 turn on or off according to signals 22 and 26. When at least one of JFETs 12-16 is turned off, it creates an open circuit condition whereby current cannot flow from an input port 30 to an output port 32. When all of the JFETs 12-16 are turned on, they form a path for current to flow between input port 30 and output port 32. Moreover, when all of the JFETs 12-16 are turned on, the input voltage signal 20 is passed to output port 32 as output voltage signal 28. Thus, a logic low at input port 30 will be passed as a logic low to output port 32. Similarly, a logic high at input port 30 will be passed as a logic high to output port 32. Because circuit 10 is configured using depletion mode transistors rather than enhancement mode transistors, the conductivity of circuit 10 is increased. Passgate circuit 10 therefore forms a logic element that may be used in a wide variety of applications.

First depletion mode n-channel JFET 12 comprises a junction field effect transistor having n-type semiconductor material in its channel region. JFET 12 receives first control signal 22 at a gate terminal 40. Depletion mode p-channel JFET 14 comprises a junction field effect transistor having p-type semiconductor material in its channel region. JFET 14 receives second control signal 26 at a gate terminal 42. Second depletion mode n-channel JFET 16 comprises a junction field effect transistor having n-type semiconductor material in its channel region. JFET 16 receives first control signal 22 at a gate terminal 44. Inverter 24 comprises any suitable number and combination of electrical circuit elements that convert a logic low signal to a logic high signal, and a logic high signal to a logic low signal.

First control signal 22 comprises an “enable” signal having a voltage of either zero volts or Vdd. Second control signal 26 comprises an “enable bar” signal having the opposite voltage of signal 22. Thus, if signal 22 is zero volts, then signal 26 comprises Vdd. If signal 22 is at Vdd, then signal 26 is zero volts. In a particular embodiment, Vdd is maintained at a voltage greater than |Vtp|+|Vtn|, where Vtp is the threshold voltage of p-channel JFET 14 and Vtn is the threshold voltage of n-channel JFETs 12 or 16. Input signal 20 comprises a voltage signal that is either zero volts (e.g., logic low) or Vdd (e.g., logic high). Output signal 28 comprises a voltage signal that is either zero volts (e.g., logic low) or Vdd (e.g., logic high).

FIG. 2 is one embodiment of a table 100 that illustrates the operational characteristics of circuit 10. Table 100 comprises columns 102-112 and rows 120-130. Columns 102 and 104 identify the voltage of first control signal 22 and second control signal 26, respectively. Columns 106 and 112 identify the voltage of input signal 20 and output signal 28, respectively. Column 108 identifies the voltage at node 50 between JFET 12 and JFET 14. Column 110 identifies the voltage at node 52 between JFET 14 and JFET 16. Rows 120-126 identify the operational characteristics of circuit 10 when at least one of JFETs 12-16 is turned off by having first control signal 22 at a logic low, or at zero volts, and by having second control signal 26 at a logic high, or at Vdd. Rows 128-130 identify the operational characteristics of circuit 10 when each of the JFETs 12-16 is turned on by having first control signal 22 at a logic high, or at Vdd, and by having second control signal 26 at a logic low, or at zero volts.

Referring to row 120, the voltage conditions set forth in columns 106-112 cause JFET 12 to be turned on, JFET 14 to be turned off, and JFET 16 to be turned on. The net effect is that circuit 10 is turned off. Referring to row 122, the voltage conditions set forth in columns 106-112 cause JFET 12 to be turned off, JFET 14 to be turned off, and JFET 16 to be turned on. The net effect is that circuit 10 is turned off. Referring to row 124, the voltage conditions set forth in columns 106-112 cause JFET 12 to be turned on, JFET 14 to be turned off, and JFET 16 to be turned off. The net effect is that circuit 10 is turned off. Referring to row 126, the voltage conditions set forth in columns 106-112 cause JFET 12 to be turned off, JFET 14 to be turned on, and JFET 16 to be turned off. The net effect is that circuit 10 is turned off.

Referring now to row 128, the voltage conditions set forth in columns 106-110 cause each of JFETs 12-16 to be turned on. The net effect is that circuit 10 is turned on. As a result, the logic low of input signal 22 is passed as a logic low to output signal 26. Referring to row 130, the voltage conditions set forth in columns 106-110 cause each of JFETs 12-16 to be turned on. The net effect is that circuit 10 is turned on. As a result, the logic high of input signal 22 is passed as a logic high to output signal 26.

A particular advantage of circuit 10 is that by using depletion mode transistors such as JFETs 12-16 rather than enhancement mode devices like CMOS transistors, the current between input port 30 and output port 32 is stronger. As a result, the resistivity of the circuit 10 is lower (and the conductivity is higher) than a comparable passgate circuit that uses enhancement mode transistors. In addition, circuit 10 does not need to use any level translators in order to create appropriate voltages to turn off one or more transistors. Furthermore, circuit 10 does not experience a significant voltage drop from input port 30 to output port 32 due to threshold voltages of JFETs 12-16. Instead, a substantially full rail-to-rail voltage swing is achievable from input port 30 to output port 32. In this regard, whatever voltage that is applied at input port 30 is communicated to output port 32.

Although the present invention has been described in detail, it should be understood that various changes, substitutions and alterations can be made hereto without departing from the sphere and scope of the invention as defined by the appended claims.

What is claimed is:

1. A passgate circuit, comprising:
a first depletion mode n-channel JFET having a first terminal coupled to an input port, a second terminal that receives a first control signal, and a third terminal;
a depletion mode p-channel JFET having a first terminal coupled to the third terminal of the first depletion mode n-channel JFET, a second terminal that receives a second control signal, and a third terminal; and
a second depletion mode n-channel JFET having a first terminal coupled to the third terminal of the depletion mode p-channel JFET, a second terminal that receives the first control signal, and a third terminal coupled to an output port.

2. The circuit of claim 1, wherein at least one of the first depletion mode n-channel JFET, the depletion mode p-channel JFET, and the second depletion mode n-channel JFET is turned off when the first control signal is at a low voltage.

3. The circuit of claim 2, wherein the second control signal is at a high voltage when the first control signal is at a low voltage.

4. The circuit of claim 2, wherein the JFET that is turned off forms an open circuit so that current cannot flow between the input port and the output port.

5. The circuit of claim 1, wherein each of the first depletion mode n-channel JFET, the depletion mode p-channel JFET, and the second depletion mode n-channel JFET is turned on when the first control signal is at a high voltage.

6. The circuit of claim 5, wherein the second control signal is at a low voltage when the first control signal is at a high voltage.

7. The circuit of claim 5, wherein each of the JFETs that are turned on form a path for current to flow between the input port and the output port.

8. The circuit of claim 5, wherein an input signal received at the input port is communicated as an output signal at the output port.

9. The circuit of claim 8, wherein the input signal is a logic low signal and the output signal is a logic low signal.

10. The circuit of claim 8, wherein the input signal is a logic high signal and the output signal is a logic high signal.

11. The circuit of claim 1, further comprising an inverter operable to generate the second control signal based at least in part upon the first control signal.

12. The circuit of claim 1, wherein the second terminal of the first depletion mode n-channel JFET comprises a gate terminal.

13. The circuit of claim 1, wherein the second terminal of the depletion mode p-channel JFET comprises a gate terminal.

14. The circuit of claim 1, wherein the second terminal of the second depletion mode n-channel JFET comprises a gate terminal.

15. The circuit of claim 1, wherein the low voltage is approximately zero volts.

16. The circuit of claim 5, wherein the high voltage is approximately one-half volt.

17. A method for operating a passgate circuit, comprising:
receiving a first control signal at a first depletion mode n-channel JFET coupled to an input port;
receiving the first control signal at a second depletion mode n-channel JFET coupled to an output port;
receiving a second control signal at a depletion mode p-channel JFET coupled to the first and second depletion mode n-channel JFETs;
operating the JFETs such that at least one of the JFETs is turned off if the first control signal is at a low voltage and the second control signal is at a high voltage; and
operating the JFETs such that each of the JFETs is turned on if the first control signal is at a high voltage and the second control signal is at a low voltage.

18. The method of claim 17, wherein if at least one JFET is turned off, it forms an open circuit so that current cannot flow between the input port and the output port.

19. The method of claim 17, wherein if each of the JFETs is turned on, they form a path for current to flow between the input port and the output port.

20. The method of claim 17, wherein if each of the JFETs is turned on, an input signal received at the input port is communicated as an output signal at the output port.

21. The method of claim 20, wherein the input signal is a logic low signal and the output signal is a logic low signal.

22. The method of claim 20, wherein the input signal is a logic high signal and the output signal is a logic high signal.

23. The method of claim 20, wherein the low voltage is approximately zero volts.

24. The circuit of claim 20, wherein the high voltage is approximately one-half volt.

25. A passgate circuit, comprising:
a first depletion mode n-channel JFET coupled to an input port and operable to receive a first control signal;
a depletion mode p-channel JFET coupled in series with the first depletion mode n-channel JFET and operable to receive a second control signal; and
a second depletion mode n-channel JFET coupled in series with the depletion mode p-channel JFET and to an output port, and operable to receive the first control signal.

26. The circuit of claim 25, wherein the JFETs are operable to communicate a voltage signal applied at the input port to the output port in response to the first and second control signals.

27. The circuit of claim 26, wherein the communication of the voltage signal from the input port to the output port comprises a rail-to-rail voltage swing.

28. The circuit of claim 25, wherein at least one of the first depletion mode n-channel JFET, the depletion mode p-channel JFET, and the second depletion mode n-channel JFET is turned off when the first control signal is at a low voltage.

29. The circuit of claim 28, wherein the second control signal is at a high voltage when the first control signal is at a low voltage.

30. The circuit of claim 28, wherein the JFET that is turned off forms an open circuit.

31. The circuit of claim 25, wherein each of the first depletion mode n-channel JFET, the depletion mode p-channel JFET, and the second depletion mode n-channel JFET is turned on when the first control signal is at a high voltage.

32. The circuit of claim 31, wherein the second control signal is at a low voltage when the first control signal is at a high voltage.

33. The circuit of claim 31, wherein each of the JFETs that are turned on form a path for current to flow between the input port and the output port.
